(19) United States
(12) Patent Application Publication
(10) Pub. No.: US 2018/0175590 A1
(43) Pub. Date: Jun. 21, 2018

(54) SEMICONDUCTOR LASER DEVICE

(71) Applicant: Mitsubishi Electric Corporation, Chiyoda-ku (JP)

(72) Inventors: Tatsuya YAMAMOTO, Tokyo (JP); Daiji MORITA, Tokyo (JP); Masato KAWASAKI, Tokyo (JP); Kazuki KUBA, Tokyo (JP); Junichi NISHIMAE, Tokyo (JP); Tetsuo KOJIMA, Tokyo (JP)

(73) Assignee: Mitsubishi Electric Corporation, Chiyoda-ku (JP)

(21) Appl. No.: 15/579,780

(22) PCT Filed: Dec. 25, 2015
(86) PCT No.: PCT/JP2015/086380

§ 371 Date: Dec. 5, 2017

(30) Foreign Application Priority Data
Aug. 4, 2015 (JP) 2015-154260

(51) Int. Cl. H01S 5/14; H01S 5/00; H01S 5/022; H01S 5/40; H01S 5/22

(52) U.S. Cl. CPC H01S 5/146; H01S 5/0078; H01S 5/22; H01S 5/02288; H01S 5/4087; H01S 5/0071

(57) ABSTRACT

A semiconductor laser device includes: a semiconductor laser bar to output a plurality of beams with different wavelengths from a continuous light-emitting region; a light-condensing optical system to condense the beams; a wavelength-dispersive optical element having a wavelength dispersing function; an optical filter in which a wavelength of a beam that passes therethrough differs periodically; an aperture located on an optical path of the beams superimposed on an identical axis; and a partially reflecting mirror. A totally reflecting mirror is formed on a back side of the semiconductor laser bar, and wavelengths of a plurality of beams with different wavelengths reflected by the totally reflecting mirror and output from the semiconductor laser bar are respectively identical to wavelengths of beams that pass through the optical filter.

### FIELD

The present invention relates to a semiconductor laser device that performs optical amplification using a resonator.

### BACKGROUND

There is a known technique for conventional semiconductor laser devices in order to improve the beam quality of a semiconductor laser bar. In the known technique, beams from the respective light-emitting points of the semiconductor laser bar are condensed on a wavelength-dispersive optical element by using a lens after the divergence angle of the beams is corrected and the beams from the respective light-emitting points are then superimposed on one another by using wavelength dispersive properties of the wavelength-dispersive optical element, and a partially reflecting mirror is provided for the superimposed beams, thereby constituting an external resonator (for example, Patent Literature 1).

### CITATION LIST

### Patent Literature

Patent Literature 1: US Patent Application Laid-open No. 2011/0216417

### SUMMARY

### Technical Problem

However, if the technique described in Patent Literature 1 is applied to a broad-area semiconductor laser device that outputs a plurality of beams with different wavelengths from a continuous light-emitting region extending in a lateral direction of a semiconductor laser bar, it is difficult to obtain laser light with high beam quality simply by superimposing a plurality of beams with different wavelengths on one another. This is because the divergence angle in a slow-axis direction at a single light-emitting point is large. The slow-axis direction refers to an X-axis direction. The beam quality can be improved by downsizing a single light-emitting point of the semiconductor laser. However, by doing this, only the laser devices with low efficiency and low output are obtained.

The present invention has been achieved to solve the above problems, and an object of the present invention is to provide a semiconductor laser device that is highly efficient and can improve the quality of a plurality of beams with different wavelengths that are output from a continuous light-emitting region extending in a lateral direction of a semiconductor laser bar.

### Solution to Problem

To solve the above problems and achieve the object, a semiconductor laser device according to an aspect of the present invention includes: a semiconductor laser bar to output a plurality of beams with different wavelengths from a continuous light-emitting region; a light-condensing lens to condense the beams; a wavelength-dispersive optical element located at a position where the beams are condensed and having a wavelength dispersing function; an optical filter in which a wavelength of a beam that passes therethrough differs periodically; and an aperture. A totally reflecting mirror is formed on a back side of the semiconductor laser bar, and wavelengths of a plurality of beams with different wavelengths reflected by the totally reflecting mirror and output from the semiconductor laser bar are respectively identical to a plurality of wavelengths of beams that pass through the optical filter.

### Advantageous Effects of Invention

According to the present invention, an effect is obtained where the semiconductor laser device can superimpose a plurality of beams with different wavelengths that are output from a continuous light-emitting region while improving the quality of the beams and, moreover, can improve the efficiency.

### BRIEF DESCRIPTION OF DRAWINGS

FIG. 1 is a perspective view illustrating the configuration of a semiconductor laser device according to a first embodiment.

FIG. 2 is a top view illustrating the configuration of the semiconductor laser device according to the first embodiment.

FIG. 3 is a diagram illustrating the relation between wavelengths and transmittance of an optical filter according to the first embodiment.

FIG. 4 is a perspective view illustrating the configuration of a semiconductor laser bar according to the first embodiment.

FIG. 5 is a diagram illustrating a light-emitting surface and a temperature distribution in a slow-axis direction of the semiconductor laser bar according to the first embodiment.

FIG. 6 is a diagram illustrating a refractive-index distribution of the semiconductor laser bar in the slow-axis direction according to the first embodiment.

FIG. 7 is a diagram illustrating individual beam profiles observed in the semiconductor laser bar according to the first embodiment when a plurality of beams output from the semiconductor laser bar reciprocate through a resonator once.

FIG. 8 is a diagram illustrating a composite beam profile when the individual beam profiles illustrated in FIG. 7 are combined.

FIG. 9 is a diagram illustrating an individual beam profile observed in a partially reflecting mirror when a plurality of beams output from the semiconductor laser bar according to the first embodiment reciprocate through the resonator once.

FIG. 10 is a diagram illustrating individual beam profiles observed in the semiconductor laser bar according to the first embodiment when a plurality of beams output from the semiconductor laser bar reciprocate through the resonator 20 times.

FIG. 11 is a diagram illustrating a composite beam profile when the individual beam profiles illustrated in FIG. 10 are combined.

FIG. 12 is a diagram illustrating an individual beam profile observed in the partially reflecting mirror when a plurality of beams output from the semiconductor laser bar according to the first embodiment reciprocate through the resonator 20 times.

FIG. 13 is a perspective view illustrating the configuration of a semiconductor laser device according to a second embodiment.

FIG. 14 is a diagram illustrating change in a beam diameter on an optical path of a resonator in the semiconductor laser device according to the second embodiment.

FIG. 15 is a diagram illustrating a beam profile in a case where the beam radius is equal to the beam overlapping pitch in the semiconductor laser device according to the second embodiment.

FIG. 16 is a diagram illustrating a beam profile in a case where the beam radius is half the beam overlapping pitch in the semiconductor laser device according to the second embodiment.

FIG. 17 is a diagram illustrating the entire beam intensity ratio in the semiconductor laser bar relative to the ratio between the beam radius and the beam overlapping pitch in the semiconductor laser device according to the second embodiment.

FIG. 18 is a perspective view illustrating the configuration of a semiconductor laser device according to a third embodiment.

FIG. 19 is a diagram illustrating the reflectivity of a partially reflecting mirror in the semiconductor laser device according to the third embodiment.

FIG. 20 is a diagram illustrating the reflectivity of the partially reflecting mirror in the semiconductor laser device according to the third embodiment.

FIG. 21 is a perspective view illustrating the configuration of a semiconductor laser device according to a fourth embodiment.

FIG. 22 is a perspective view illustrating the configuration of a semiconductor laser device according to a fifth embodiment.

FIG. 23 is a perspective view illustrating the configuration of a semiconductor laser device according to a sixth embodiment.

FIG. 24 is a perspective view illustrating the configuration of a semiconductor laser device according to a seventh embodiment.

FIG. 25 is a perspective view illustrating the configuration of a semiconductor laser device according to an eighth embodiment.

FIG. 26 is a perspective view illustrating the configuration of a semiconductor laser device according to a ninth embodiment.

FIG. 27 is a diagram illustrating the reflectivity of an etalon according to the ninth embodiment.

FIG. 28 is a top view illustrating the configuration of a semiconductor laser device according to a tenth embodiment.

FIG. 29 is a perspective view illustrating the configuration of a semiconductor laser device according to an eleventh embodiment.

FIG. 30 is a perspective view illustrating the configuration of a semiconductor laser device according to a twelfth embodiment.

FIG. 31 is a top view illustrating a propagation path of unnecessary light within the semiconductor laser bar according to the first to eleventh embodiments.

FIG. 32 is a top view illustrating a semiconductor laser bar according to the twelfth embodiment.

FIG. 33 is a top view illustrating the configuration of a semiconductor laser device according to a thirteenth embodiment.

FIG. 34 is a top view illustrating the configuration of a semiconductor laser device according to a fourteenth embodiment.

FIG. 35 is a front view of a semiconductor laser bar according to the fourteenth embodiment.

FIG. 36 is a top view illustrating the configuration of a semiconductor laser device according to a fifteenth embodiment.

FIG. 37 is a front view of a semiconductor laser bar according to the fifteenth embodiment.

FIG. 38 is a diagram illustrating a beam profile of a conventional semiconductor laser device.

### DESCRIPTION OF EMBODIMENTS

A semiconductor laser device according to embodiments of the present invention will be explained below in detail with reference to the accompanying drawings. The present invention is not limited to the embodiments.

### First Embodiment

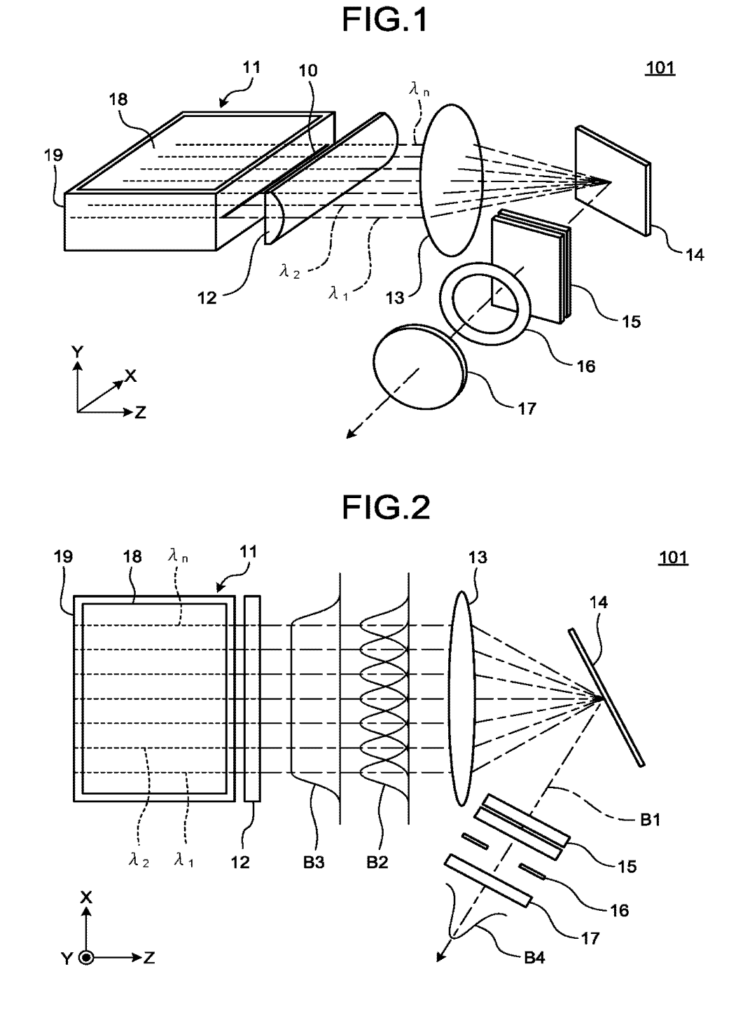

FIG. 1 is a perspective view illustrating the configuration of a semiconductor laser device 101 according to a first embodiment. The semiconductor laser device 101 includes a semiconductor laser bar 11 including a continuous light-emitting region 10 extending in a lateral direction of the semiconductor laser bar; a beam divergence-angle correction optical system 12 that corrects the divergence angle of a beam; a light-condensing optical system 13 that is a condensing lens that condenses beams, a wavelength-dispersive optical element 14 having a wavelength dispersing function; an optical filter 15 that allows only the incident light having a wavelength within a predetermined range to pass therethrough; an aperture 16 through which a beam within a predetermined range passes; and a partially reflecting mirror 17 that outputs some of the beams to external destinations while reflecting the remaining beams to the aperture 16. The lateral direction refers to an X-axis direction illustrated in FIG. 1.

The semiconductor laser bar 11 outputs a plurality of beams with different wavelengths from a continuous light-emitting region. In the semiconductor laser bar 11, for example, an electrode 18 is formed over the entire surface of the semiconductor laser bar 11 in order to generate a continuous light-emitting region. A totally reflecting mirror 19 is formed on the surface of the semiconductor laser bar 11 facing the light-emitting surface. In the semiconductor laser device 101, a resonator is constituted between the partially reflecting mirror 17 and the totally reflecting mirror 19.

The beam divergence-angle correction optical system 12 corrects the divergence angle of a plurality of beams with different wavelengths output from the semiconductor laser bar 11.

The light-condensing optical system 13 condenses the beams. The light-condensing optical system 13 is a cylindrical lens.

The wavelength-dispersive optical element 14 is located at a position where a plurality of beams are condensed and has a wavelength dispersing function. The wavelength-dispersive optical element 14 is a diffraction grating or a prism.

The optical filter 15 is located on an optical path of the beams that are diffracted and superimposed on an identical axis by the wavelength-dispersive optical element 14. The wavelength of the beams that pass through the optical filter 15 differs periodically. The optical filter 15 has a periodic transmittance distribution relative to the light wavelength, and is configured to have high transmittance for light with a plurality of beam wavelengths (λ1, λ2, . . . , λn).

The aperture 16 is located on the optical path of the beams diffracted and superimposed on an identical axis by the wavelength-dispersive optical element 14. While the aperture 16 has a circular opening in the example illustrated in FIG. 1, it is also possible that the aperture 16 has a rectangular opening.

The partially reflecting mirror 17 is located at the subsequent stage of the aperture 16 and on the optical path of the beams diffracted and superimposed on an identical axis by the wavelength-dispersive optical element 14.

The totally reflecting mirror 19 is formed on the back side of the semiconductor laser bar 11 to reflect a plurality of beams with different wavelengths that have been reflected by the partially reflecting mirror 17 and have then returned to the semiconductor laser bar 11.

The wavelengths of a plurality of beams with different wavelengths reflected by the totally reflecting mirror 19 and output from the semiconductor laser bar 11 are respectively identical to the wavelengths of the beams that pass through the optical filter 15.

FIG. 2 is a top view illustrating the configuration of the semiconductor laser device 101. Beams output from the semiconductor laser bar 11 are condensed on the surface of the wavelength-dispersive optical element 14 by the light-condensing optical system 13. The wavelength-dispersive optical element 14 diffracts the condensed beams at a diffraction angle corresponding to their respective wavelengths and superimposes the condensed beams on a single optical axis B1. The beams superimposed on the single optical axis B1 enter the optical filter 15. The optical filter 15 allows only the beams with a plurality of predetermined wavelengths to pass therethrough. The beams having passed through the optical filter 15 are incident on the partially reflecting mirror 17 via the aperture 16.

The partially reflecting mirror 17 has reflectivity of, for example, 5% to 20%. The beams, reflected by the partially reflecting mirror 17, follows the optical path in the reverse direction, and enters the semiconductor laser bar 11 again. The beams, having entered the semiconductor laser bar 11, are reflected by the totally reflecting mirror 19 of the semiconductor laser bar 11, and are then output from the semiconductor laser bar 11. In this manner, a plurality of beams with different wavelengths reciprocate between the totally reflecting mirror 19 and the partially reflecting mirror 17.

Because the beams that are incident on the semiconductor laser bar 11 are the beams with the wavelengths that have passed through the optical filter 15, the beams are incident at the determined positions of the semiconductor laser bar 11 that are substantially equally spaced apart. A Gaussian profile B2 is formed as a beam profile as illustrated in FIG. 2 by mode selection determined by the size of the opening of the aperture 16. When beams enter the semiconductor laser bar 11, the beams have a beam profile B3 with a generally uniform distribution as illustrated in FIG. 2.

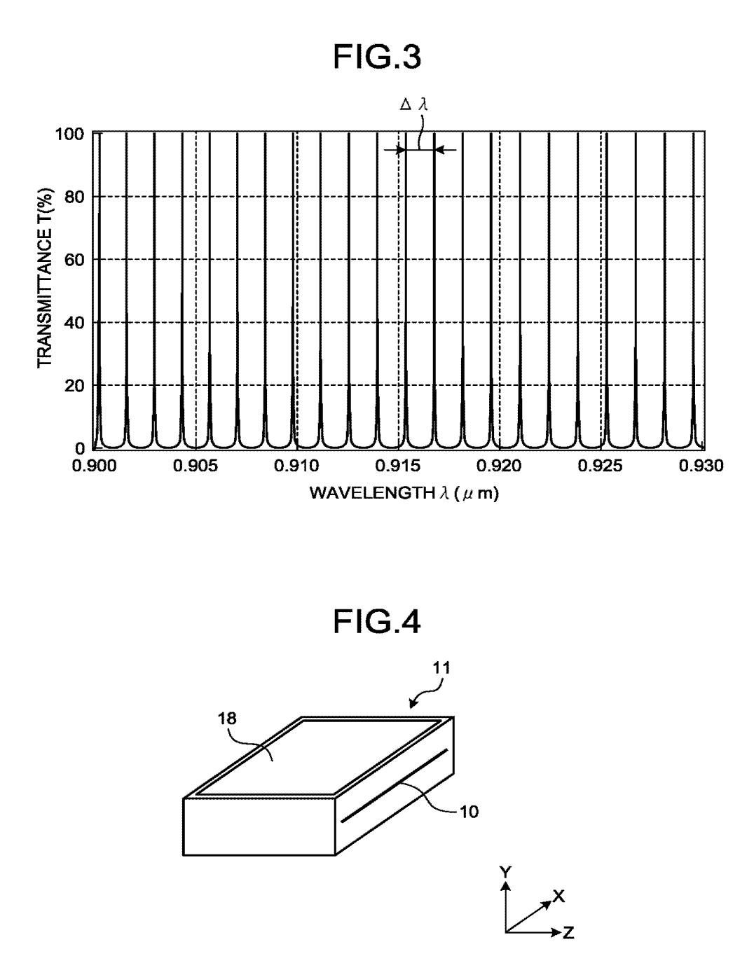

An etalon is, for example, used as the optical filter 15. FIG. 3 illustrates a spectrum of transmission intensity of an etalon. FIG. 3 illustrates an example of a solid etalon with reflectivity of 90%, a refractive index of 1.5, a thickness of 200 μm, and an incident angle of 5 degrees. Δλ in FIG. 3 is referred to as “Free Spectral Range (FSR)” and indicates a wavelength interval between the peak positions with high transmittance.

As illustrated in FIG. 3, when the value of FSR is properly set, the solid etalon exhibits transmittance characteristics having a peak at a plurality of wavelengths. Therefore, the transmittance characteristics are such that approximately 100% of the beams with a plurality of predetermined wavelengths pass through the solid etalon, while beams with wavelengths other than the predetermined wavelengths substantially do not pass through the solid etalon.

For example, when the semiconductor laser bar 11 has a gain width ranging from 900 nm to 930 nm, the semiconductor laser device 101 performs laser oscillation at 22 different wavelengths as illustrated in FIG. 3 and can superimpose the 22 beams on one another. Because each individual wavelength of the superimposed beams has a Gaussian profile, a beam B4 output from the partially reflecting mirror 17 also has a Gaussian profile shape as illustrated in FIG. 2.

Therefore, by using an etalon as the optical filter 15, the semiconductor laser device 101 can control the diffraction angle of the beams to be diffracted by the wavelength-dispersive optical element 14, and accordingly can cause the beams to be incident at equally spaced-apart positions of the semiconductor laser bar 11.

In the semiconductor laser device 101, it is possible to insert a wavelength plate such as a λ/2-wavelength plate into the optical path leading to the wavelength-dispersive optical element 14 so that S-polarized light is incident on the wavelength-dispersive optical element 14. Due to this configuration, the semiconductor laser device 101 can improve the diffraction efficiency of the wavelength-dispersive optical element 14.

In a conventional semiconductor laser device, the diffraction angle of a grating is determined by the position of the light-emitting point of a semiconductor laser in such a manner as to satisfy resonant conditions between the light-emitting point of the semiconductor laser and an output coupler. Accordingly, the wavelength is determined automatically.

In contrast, the semiconductor laser device 101 according to the first embodiment can emit light from the entire light-emitting region 10 of the semiconductor laser bar 11. Thus, the light-emitting point can be at any position in the light-emitting region 10; therefore, the semiconductor laser device 101 is configured such that the diffraction angle of a grating is not determined solely in accordance with the semiconductor laser bar. The semiconductor laser device 101 in the present invention uses the optical filter 15 to select the oscillation wavelength and determine the diffraction angle of a grating.

Next, the temperature and the refractive-index distribution in the semiconductor laser bar 11 are described. FIG. 4 is a perspective view illustrating the semiconductor laser bar 11 in detail. For example, the semiconductor laser bar 11 has a width of approximately 10 mm in the X-axis direction, which is the slow-axis direction. An anti-reflection (AR) coating is applied to the surface formed with the light-emitting region 10.

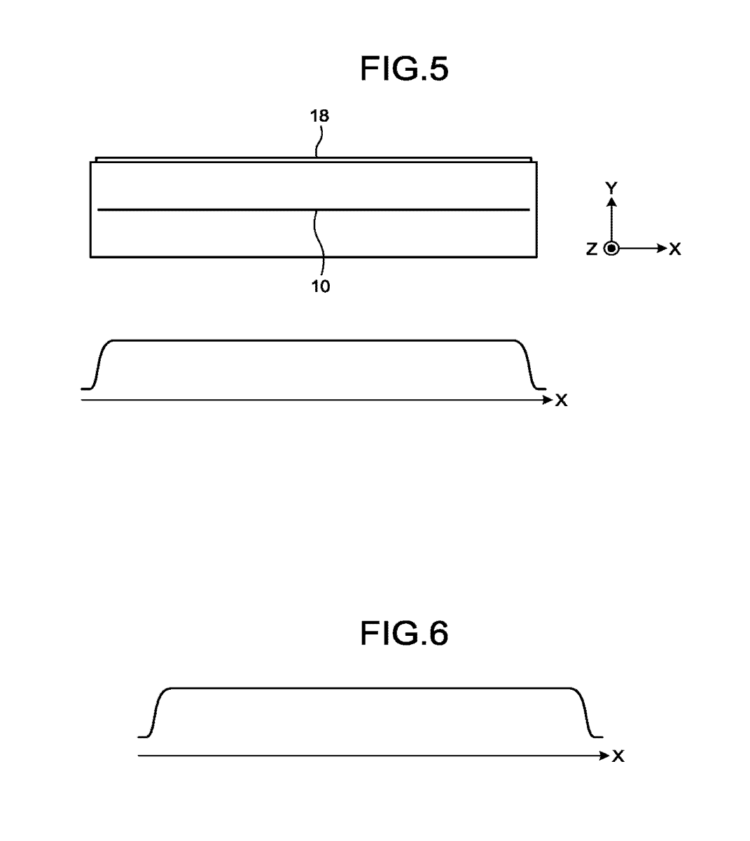

FIG. 5 illustrates a front view of the semiconductor laser bar 11 as viewed from the surface formed with the light-emitting region 10 and the temperature distribution in the slow-axis direction. FIG. 6 is a diagram illustrating the refractive-index distribution of the semiconductor laser bar 11 in the slow-axis direction. Current is applied to the semiconductor laser bar 11 uniformly in the slow-axis direction, and thereby the semiconductor laser bar 11 has a uniform gain distribution. With this gain distribution, the semiconductor laser bar 11 has a uniform temperature distribution of the generated heat as illustrated in FIG. 5. As illustrated in FIG. 6, the refractive-index distribution attributable to the dependency of a material's refractive index on temperature is also uniform in the slow-axis direction.

Therefore, the semiconductor laser bar 11 does not have a refractive-index boundary in the slow-axis direction. Beams that pass through the semiconductor laser bar 11 behave substantially identically to beams that propagate in free space. A conventional broad-area semiconductor laser has a refractive-index boundary in the slow-axis direction, and beams propagate in a waveguide mode; therefore, it is difficult to improve the beam quality in the slow-axis direction. However, the semiconductor laser bar 11 in the present invention can improve the beam quality because beams behave substantially identically to beams that propagate in free space.

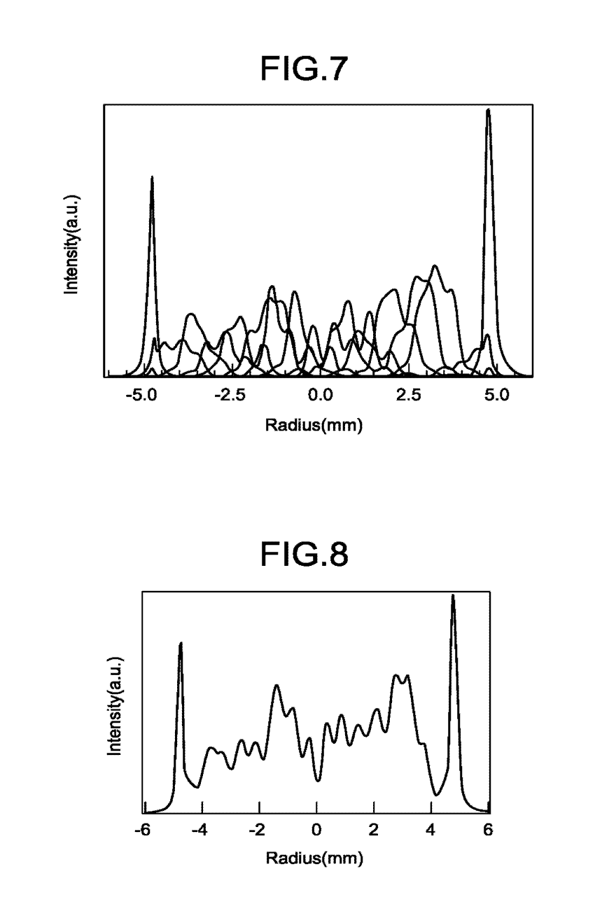

Simulation results of laser oscillation in the semiconductor laser device 101 are described below with reference to FIGS. 7 to 12. FIGS. 7 to 12 illustrate profiles of beams that reciprocate through a resonator constituted between the partially reflecting mirror 17 and the totally reflecting mirror 19.

FIG. 7 is a diagram illustrating individual beam profiles observed in the semiconductor laser bar 11 when a plurality of beams output from the semiconductor laser bar 11 reciprocate through the resonator once. The semiconductor laser bar 11 outputs beams with a random intensity distribution as an initial value. The beam profiles illustrated in FIG. 7 are obtained when the beams reciprocate through the resonator once and then enter the semiconductor laser bar 11. For example, the number of beams is 16.

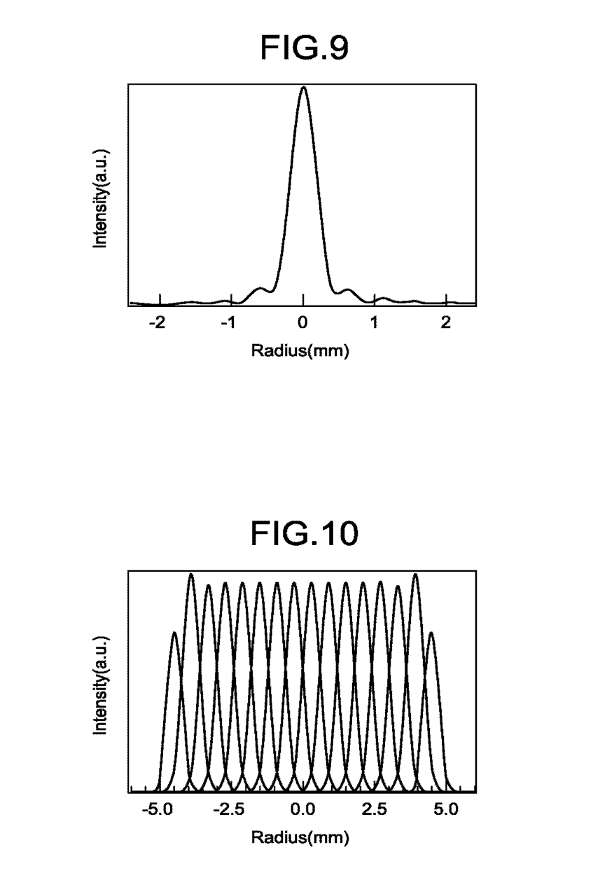

FIG. 8 is a diagram illustrating a composite beam profile when the individual beam profiles illustrated in FIG. 7 are combined.

FIG. 9 is a diagram illustrating an individual beam profile observed in the partially reflecting mirror 17 when a plurality of beams output from the semiconductor laser bar 11 reciprocate through the resonator once. The beam profile illustrated in FIG. 9 results from the sum of the profiles of 16 beams.

FIG. 10 is a diagram illustrating individual beam profiles observed in the semiconductor laser bar 11 when a plurality of beams output from the semiconductor laser bar 11 reciprocate through the resonator 20 times.

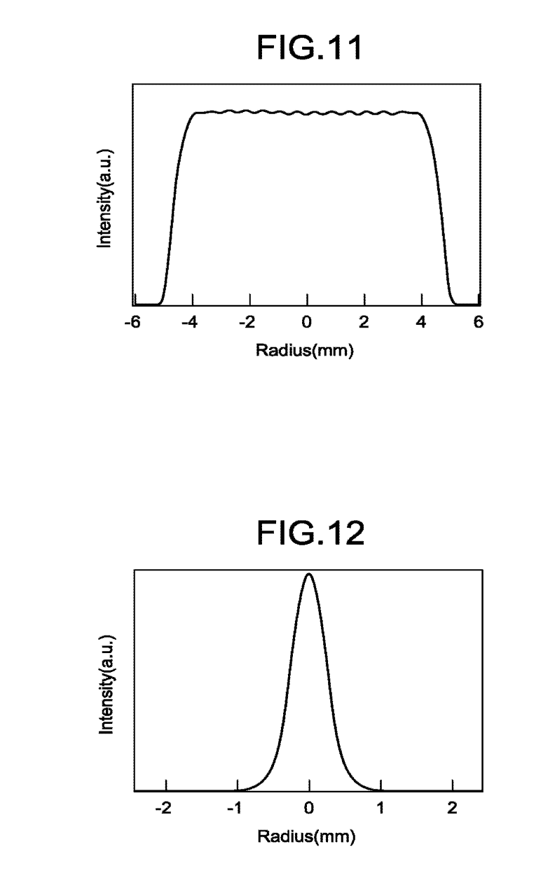

FIG. 11 is a diagram illustrating a composite beam profile when the individual beam profiles illustrated in FIG. 10 are combined.

FIG. 12 is a diagram illustrating an individual beam profile observed in the partially reflecting mirror 17 when a plurality of beams output from the semiconductor laser bar 11 reciprocate through the resonator 20 times.

The gain width that is the width of the semiconductor laser bar 11 in the slow-axis direction is, for example, 10 mm. Therefore, the interval between beams with different wavelengths is 0.6 mm.

When a plurality of beams output from the semiconductor laser bar 11 reciprocate through the resonator once, there are wide variations in the intensity distribution between 16 beams as illustrated in FIG. 7. When 16 beam profiles are combined, the composite beam profile exhibits significant change in the intensity distribution as illustrated in FIG. 8. As illustrated in FIG. 9, a side lobe appears in the beam profile observed in the partially reflecting mirror 17 when a plurality of beams output from the semiconductor laser bar 11 reciprocate through the resonator once.

In contrast, in a case where a plurality of beams output from the semiconductor laser bar 11 of the semiconductor laser device 101 reciprocate through the resonator 20 times, individual beam profiles observed in the semiconductor laser bar 11 become substantially a Gaussian profile as illustrated in FIG. 10. When 16 beam profiles are combined, the composite profile exhibits a substantially uniform intensity distribution as illustrated in FIG. 11. When a plurality of beams output from the semiconductor laser bar 11 reciprocate through the resonator 20 times, the beam profile observed in the partially reflecting mirror 17 becomes a Gaussian profile without a side lobe as illustrated in FIG. 12.

As described above, the semiconductor laser device 101 causes beams with a random intensity distribution to reciprocate many times in the resonator so as to converge the beam profiles and thus can eventually perform laser oscillation in a single mode with a Gaussian profile in which a side lobe does not appear.

In the first embodiment, the number of beams has been described as 16. However, the number of beams is not limited to 16. There can be any number of beams that is greater than one, and even if the number of beams is not 16, effects identical to those obtained in the case where the number of beams is 16 can also be obtained.

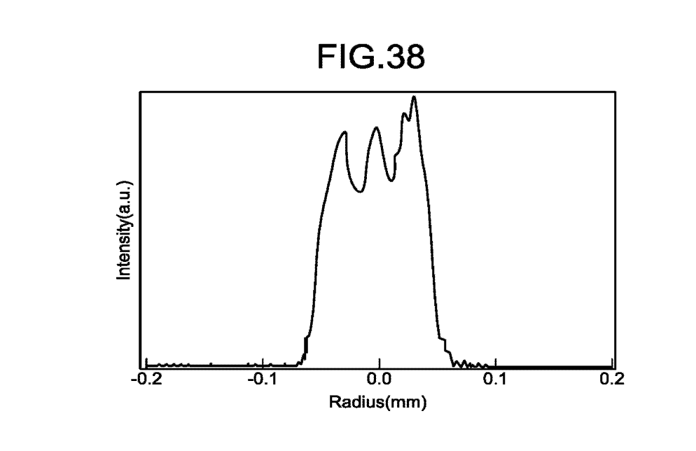

In a conventional semiconductor laser device, the beam mode in a slow-axis direction is determined by the width of a light-emitting point in the slow-axis direction. In contrast, the semiconductor laser device 101 can perform laser oscillation in a substantially arbitrary mode because the beam mode is limited by the aperture 16. By reducing the opening diameter of the aperture 16, the semiconductor laser device 101 can also perform laser oscillation in a single mode. For example, FIG. 38 illustrates actual measurement values of a beam profile of a conventional broad-area semiconductor laser. When a comparison is made between the beam profile illustrated in FIG. 38 and the beam profile in the present invention illustrated in FIG. 12, it is understood that the present invention significantly improves the beam quality. Further, the composite profile illustrated in FIG. 11 exhibits a substantially uniform intensity distribution that is substantially identical to the gain distribution of the semiconductor laser bar. That is, beams pass through the gain region without waste, and therefore the semiconductor laser can oscillate efficiently.

Accordingly, the semiconductor laser device 101 can perform laser oscillation in a single mode in the slow-axis direction, improve the quality of a plurality of beams with different wavelengths output from a continuous light-emitting region, and further improve the efficiency thereof. Improvement in the beam quality means that beams have the same wavelength, are in phase, and propagate in the same direction, and indicates that the light condensing performance is satisfactory. In the first embodiment, the optical filter 15 is located on an optical path of beams diffracted and superimposed on an identical axis by the wavelength-dispersive optical element 14. For example, it is also possible that the optical filter 15 is located between the semiconductor laser bar 11 and the light-condensing optical system 13. Further, in the first embodiment, the electrode 18 is formed over the entire surface of the semiconductor laser bar 11 in order to generate a continuous light-emitting region. However, it is also possible that an active layer is formed from one end to the other end in the lateral direction of the semiconductor laser bar 11.

### Second Embodiment

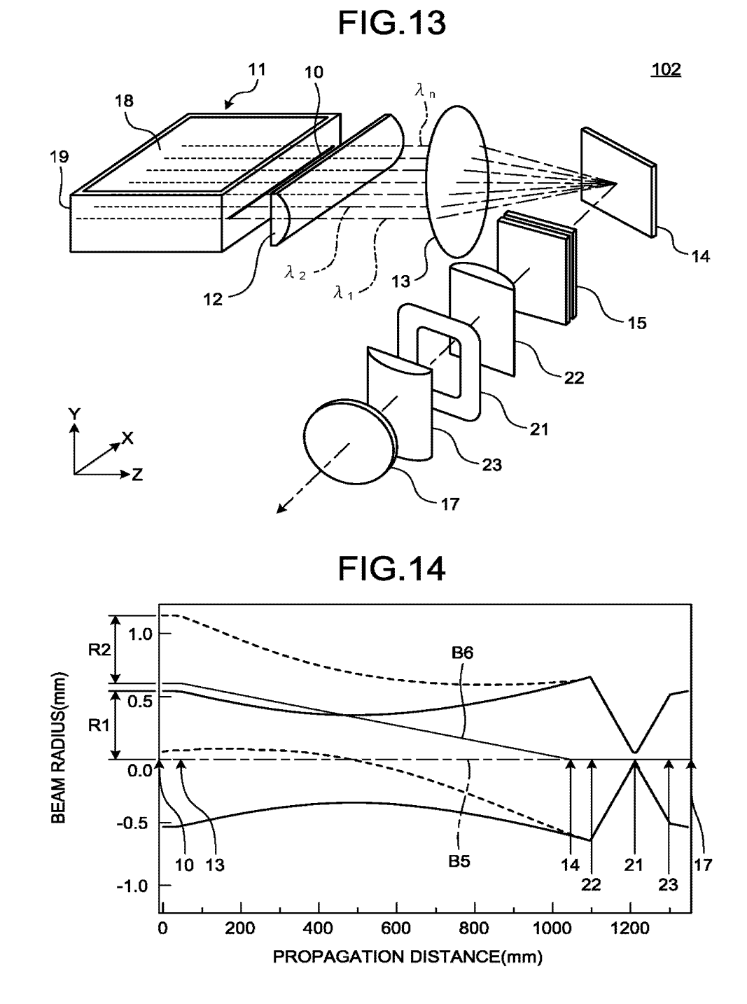

Next, a second embodiment is described. FIG. 13 is a perspective view illustrating the configuration of a semiconductor laser device 102 according to the second embodiment. In the semiconductor laser device 102 according to the second embodiment, the configuration between the optical filter 15 and the partially reflecting mirror 17 is different from that in the semiconductor laser device 101 according to the first embodiment. In the following descriptions, constituent elements identical to those of the semiconductor laser device 101 according to the first embodiment are denoted by like reference signs and explanations thereof will be omitted.

The semiconductor laser device 102 includes an aperture 21 having a rectangular opening, and cylindrical lenses 22 and 23 before and after the aperture 21. Due to this configuration, the semiconductor laser device 102 can condense beams in the slow-axis direction at a location of the aperture 21.

Therefore, the semiconductor laser device 102 can create a Fourier-transformed image at a location of the aperture 21 and thus can limit the beam mode definitely.

FIG. 14 is a diagram illustrating change in a beam diameter on an optical path of a resonator constituted between the partially reflecting mirror 17 and the totally reflecting mirror 19 of the semiconductor laser device 102. Arrows illustrated in FIG. 14 indicate the locations of the light-emitting region 10, the light-condensing optical system 13, the wavelength-dispersive optical element 14, the cylindrical lens 22, the aperture 21, the cylindrical lens 23, and the partially reflecting mirror 17. Further, FIG. 14 illustrates an optical axis B5 of a beam with a first wavelength, an optical axis B6 of a beam with a second wavelength different from the first wavelength, a beam radius R1 of the first wavelength, and a beam radius R2 of the second wavelength. While FIG. 14 illustrates only two beams for convenience of explanation, there are plurality of beams in practice.

The semiconductor laser device 102 forms a uniform intensity distribution by superimposing beams with different wavelengths in the semiconductor laser bar 11. Therefore, the relation between the beam overlapping pitch and the individual beam radius is important.

In the example illustrated in FIG. 14, the beam radius is equal to the beam overlapping pitch. The beam radius refers to a 1/e² radius and is a beam diameter at a point where the value of the beam intensity becomes 1/e² of the peak value. “e” represents the natural logarithm.

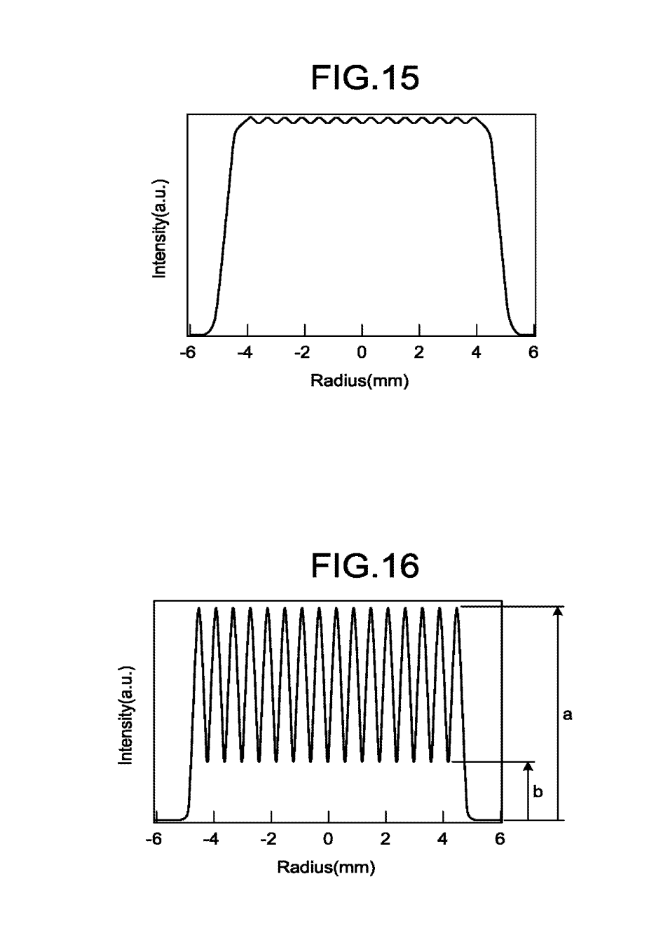

FIG. 15 is a diagram illustrating a beam profile in a case where the beam radius is equal to the beam overlapping pitch. As illustrated in FIG. 15, it is understood that the beam profile exhibits a substantially uniform distribution in its entirety.

FIG. 16 is a diagram illustrating a beam profile in a case where the beam radius is half the beam overlapping pitch. As illustrated in FIG. 16, the beam profile does not exhibit a uniform distribution. That is, FIG. 16 shows that the entire beam intensity distribution in the semiconductor laser bar 11 is not uniform.

In a lower beam intensity section, the gain of the semiconductor laser bar 11 remains. In this section, there is a possibility that the semiconductor laser bar 11 may perform laser oscillation alone and not through a resonator. This may cause mixture of laser light having low beam quality.

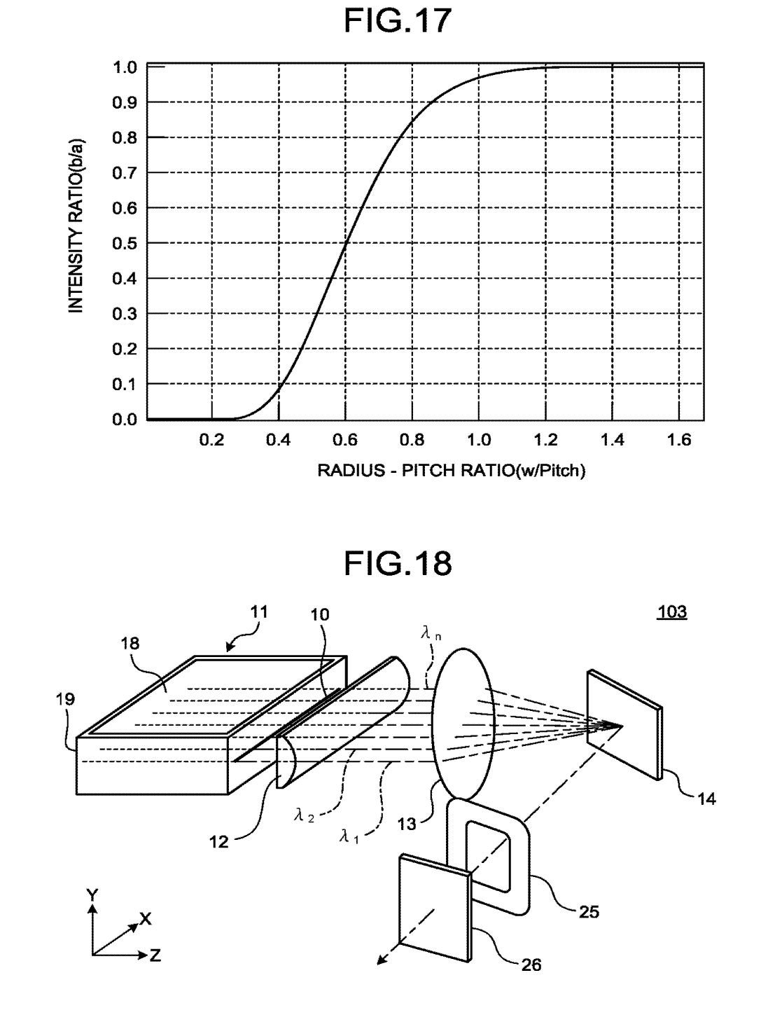

FIG. 17 is a diagram illustrating the entire beam intensity ratio b/a in the semiconductor laser bar 11 relative to the ratio between the beam radius and the beam overlapping pitch. “b” represents a lower beam intensity section in FIG. 16, and “a” represents the total beam intensity in FIG. 16. In a case where the beam intensity ratio is equal to or greater than 0.85, the ratio between the beam radius and the beam overlapping pitch needs to be greater than 0.8 as illustrated in FIG. 17.

In the semiconductor laser device 102 according to the second embodiment, there is a relation between a plurality of beams with different wavelengths, reflected by the totally reflecting mirror 19 and output from the semiconductor laser bar 11, that the ratio between each beam radius and the pitch between the optical-axis positions of the individual beams is greater than 0.8 at the output position of the semiconductor laser bar 11.

As described above, the semiconductor laser device 102 sets the ratio between each beam radius and the pitch between the optical-axis positions of the individual beams so as to be greater than 0.8 at the output position of the semiconductor laser bar 11. Accordingly, the semiconductor laser device 102 can perform laser oscillation in a single mode in the slow-axis direction and improve the quality of a plurality of beams with different wavelengths output from a continuous light-emitting region.

### Third Embodiment

Next, a third embodiment is described. FIG. 18 is a perspective view illustrating the configuration of a semiconductor laser device 103 according to the third embodiment. In the semiconductor laser device 103 according to the third embodiment, the configuration subsequent to the wavelength-dispersive optical element 14 is different from that in the semiconductor laser device 101 according to the first embodiment. In the following descriptions, constituent elements identical to those of the semiconductor laser device 101 according to the first embodiment are denoted by like reference signs and explanations thereof will be omitted.

The semiconductor laser device 103 includes an aperture 25 located on an optical path of a plurality of beams diffracted and superimposed on an identical axis by the wavelength-dispersive optical element 14, and a partially reflecting mirror 26 located on the optical path of the beams at the subsequent stage of the aperture 25.

The wavelength of beams reflected by the partially reflecting mirror 26 differs periodically. The totally reflecting mirror 19 is formed on the back side of the semiconductor laser bar 11 to reflect a plurality of beams with different wavelengths that have been reflected by the partially reflecting mirror 26 and have then returned to the semiconductor laser bar 11.

The wavelengths of a plurality of beams with different wavelengths reflected by the totally reflecting mirror 19 are respectively identical to the wavelengths of the beams reflected by the partially reflecting mirror 26.

A beam mode is selected in accordance with the size of the opening of the aperture 25. A dielectric multilayered film having wavelength selectivity is formed on the surface of the partially reflecting mirror 26, which faces the aperture 25.

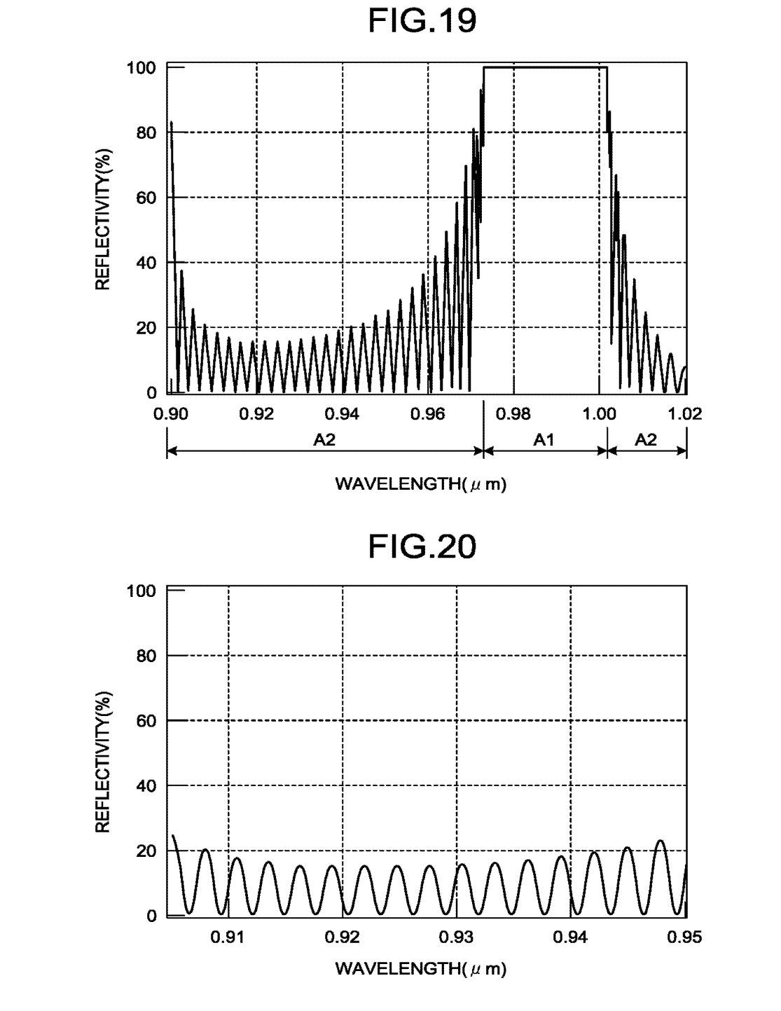

FIG. 19 is a diagram illustrating the reflectivity of the dielectric multilayered film formed on the partially reflecting mirror 26. FIG. 20 is a diagram in which the reflectivity ranging approximately from 0.91 μm to 0.95 μm illustrated in FIG. 19 is enlarged.

As illustrated in FIG. 19, the dielectric multilayered film has an area A1, in which the reflectivity is high and is not dependent on the wavelength, and an area A2, in which the reflectivity changes periodically. It is general that an area of a dielectric multilayered film where the reflectivity is high and is not dependent on the wavelength is used as a totally reflecting film. In the example illustrated in FIG. 19, the reflectivity is high and is not dependent on the wavelength in the wavelength area of approximately 0.97 μm to 1 μm.

As illustrated in FIG. 20, the reflectivity of the dielectric multilayered film changes periodically within the range from 0% to 20% relative to the wavelength area of 0.9 μm to 0.95 μm where there is a gain of the semiconductor laser bar 11.

When the above area of the dielectric multilayered film is used as a partially reflecting mirror of a resonator, the feedback factor of beams with a plurality of specific wavelengths is increased and laser oscillation is selectively performed at these wavelengths.

In the semiconductor laser device 103, only the beams with a plurality of wavelengths at which the reflectivity of the dielectric multilayered film formed on the partially reflecting mirror 26 is high are reflected toward the aperture 25. Each of the beams with the respective wavelengths is then diffracted by the wavelength-dispersive optical element 14 and can therefore be incident at a different desired position of the semiconductor laser bar 11. Accordingly, the semiconductor laser bar 11 can form a generally uniform beam intensity distribution.

Consequently, the semiconductor laser device 103 can perform laser oscillation in a single mode in the slow-axis direction, improve the quality of a plurality of beams with different wavelengths output from a continuous light-emitting region, and also improve the efficiency, similarly to the semiconductor laser device 101 according to the first embodiment.

Further, in the semiconductor laser device 103 according to the third embodiment, with respect to a plurality of beams with different wavelengths reflected by the totally reflecting mirror 19 and output from the semiconductor laser bar 11, it is preferable that the ratio between each beam radius and the pitch between the optical-axis positions of the individual beams is greater than 0.8 at the output position of the semiconductor laser bar 11. This is because when the beam intensity ratio is equal to or greater than 0.85, the ratio between the beam radius and the beam overlapping pitch needs to be greater than 0.8 as illustrated in FIG. 17.

As described above, the semiconductor laser device 103 sets the ratio between each beam radius and the pitch between the optical-axis positions of the individual beams so as to be greater than 0.8 at the output position of the semiconductor laser bar 11. Accordingly, the semiconductor laser device 103 can perform laser oscillation in a single mode in the slow-axis direction, improve the quality of a plurality of beams with different wavelengths output from a continuous light-emitting region, and also improve the efficiency.

### Fourth Embodiment

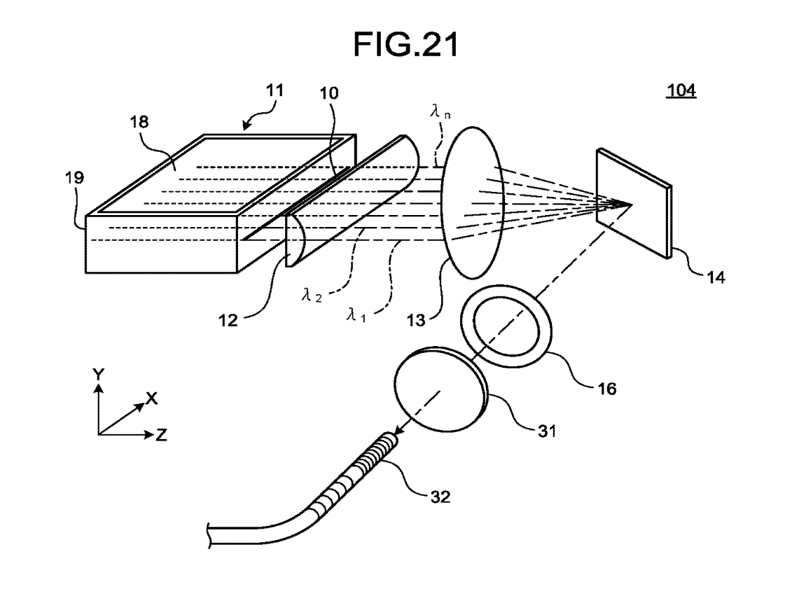

Next, a fourth embodiment is described. FIG. 21 is a perspective view illustrating the configuration of a semiconductor laser device 104 according to the fourth embodiment. In the semiconductor laser device 104 according to the fourth embodiment, the configuration subsequent to the wavelength-dispersive optical element 14 is different from that in the semiconductor laser device 101 according to the first embodiment. In the following descriptions, constituent elements identical to those of the semiconductor laser device 101 according to the first embodiment are denoted by like reference signs and explanations thereof will be omitted.

The semiconductor laser device 104 includes a light-condensing optical system 31 and a fiber Bragg grating 32. The light-condensing optical system 31 is a second light-condensing optical system that is located on an optical path of beams diffracted and superimposed on an identical axis by the wavelength-dispersive optical element 14 and condenses beams. Beams condensed by the light-condensing optical system 31 enter the fiber Bragg grating 32.

The fiber Bragg grating 32 is configured such that it has a high reflectivity for the wavelengths of a plurality of beams with different wavelengths output from the semiconductor laser bar 11.

Beams having reached the light-condensing optical system 31 from the wavelength-dispersive optical element 14 are condensed by the light-condensing optical system 31, and enter the fiber Bragg grating 32.

The fiber Bragg grating 32 is configured to partially reflect a plurality of beams with different wavelengths in its grating portion. For example, a plurality of gratings are engraved at different pitches. Only the light with a plurality of wavelengths that has selectively been reflected by the fiber Bragg grating 32 returns to the semiconductor laser bar 11.

Consequently, the semiconductor laser device 104 can perform laser oscillation in a single mode in the slow-axis direction, improve the quality of a plurality of beams with different wavelengths output from a continuous light-emitting region, and also improve the efficiency, similarly to the semiconductor laser device 101 according to the first embodiment.

### Fifth Embodiment

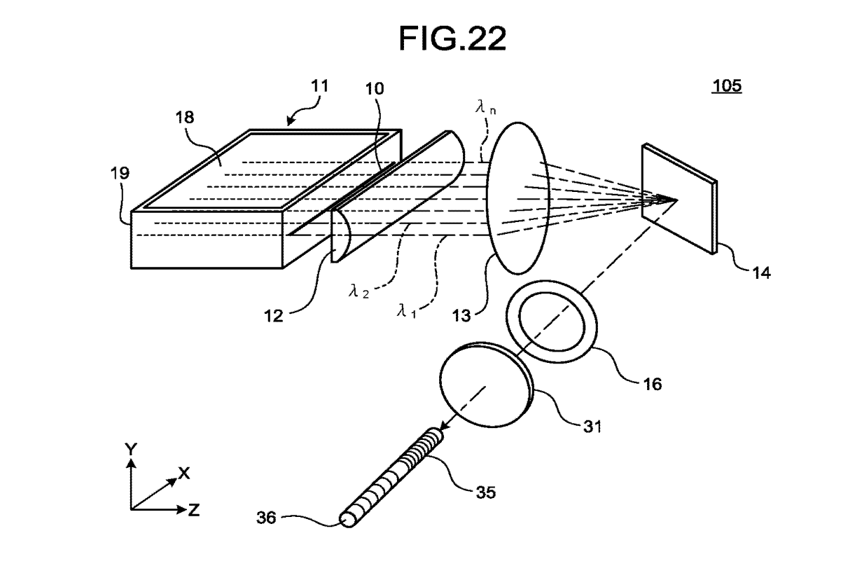

Next, a fifth embodiment is described. FIG. 22 is a perspective view illustrating the configuration of a semiconductor laser device 105 according to the fifth embodiment. In the semiconductor laser device 105 according to the fifth embodiment, the configuration of the fiber Bragg grating 32 is different from that in the semiconductor laser device 104 according to the fourth embodiment. In the following descriptions, constituent elements identical to those of the semiconductor laser device 104 according to the fourth embodiment are denoted by like reference signs and explanations thereof will be omitted.

The semiconductor laser device 105 includes a fiber Bragg grating 35 on which the beams condensed by the light-condensing optical system 31 are incident. A partially reflecting mirror 36 is formed at an output end of the fiber Bragg grating 35.

Due to this configuration, in the semiconductor laser device 105, only the light with a plurality of wavelengths that has selectively been reflected by the fiber Bragg grating 35 returns to the semiconductor laser bar 11.

Consequently, the semiconductor laser device 105 can perform laser oscillation in a single mode in the slow-axis direction, improve the quality of a plurality of beams with different wavelengths output from a continuous light-emitting region, and also improve the efficiency, similarly to the semiconductor laser device 101 according to the first embodiment.

### Sixth Embodiment

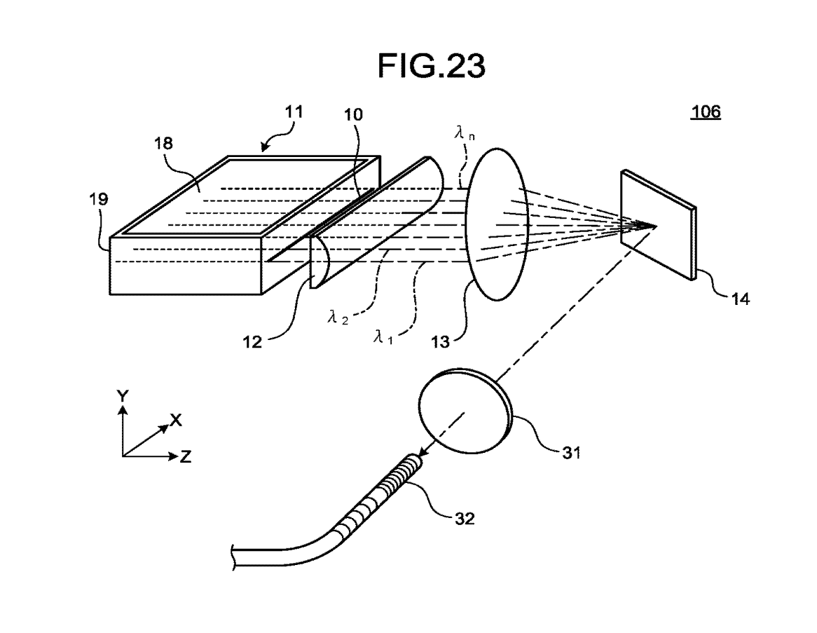

Next, a sixth embodiment is described. FIG. 23 is a perspective view illustrating the configuration of a semiconductor laser device 106 according to the sixth embodiment. In the configuration of the semiconductor laser device 106 according to the sixth embodiment, the aperture 16 in the semiconductor laser device 104 according to the fourth embodiment is omitted. In the following descriptions, constituent elements identical to those of the semiconductor laser device 104 according to the fourth embodiment are denoted by like reference signs and explanations thereof will be omitted.

The fiber Bragg grating 32 is a single-mode optical fiber. Because the fiber Bragg grating 32 is a single-mode optical fiber, the semiconductor laser device 106 can select a single mode in the fiber Bragg grating 32. Therefore, the aperture 16 can be omitted and accordingly the manufacturing costs can be reduced.

### Seventh Embodiment

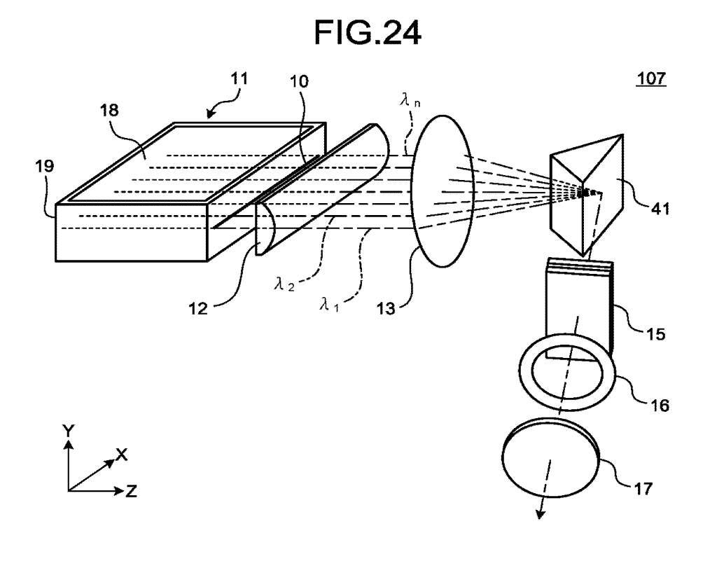

Next, a seventh embodiment is described. FIG. 24 is a perspective view illustrating the configuration of a semiconductor laser device 107 according to the seventh embodiment. The configuration of the semiconductor laser device 107 according to the seventh embodiment is different from that of the semiconductor laser device 101 according to the first embodiment in that the wavelength-dispersive optical element 14 is replaced by a prism 41. In the following descriptions, constituent elements identical to those of the semiconductor laser device 101 according to the first embodiment will be denoted by like reference signs and explanations thereof are omitted.

The wavelength-dispersive optical element 14 in the semiconductor laser device 101 according to the first embodiment is assumed to be a reflective or transmissive grating. Even when the wavelength-dispersive optical element 14 is replaced by the prism 41, the semiconductor laser device 107 according to the seventh embodiment can still perform laser oscillation in a single mode in the slow-axis direction, improve the quality of a plurality of beams with different wavelengths output from a continuous light-emitting region, and also improve the efficiency, similarly to the semiconductor laser device 101 according to the first embodiment.

### Eight Embodiment

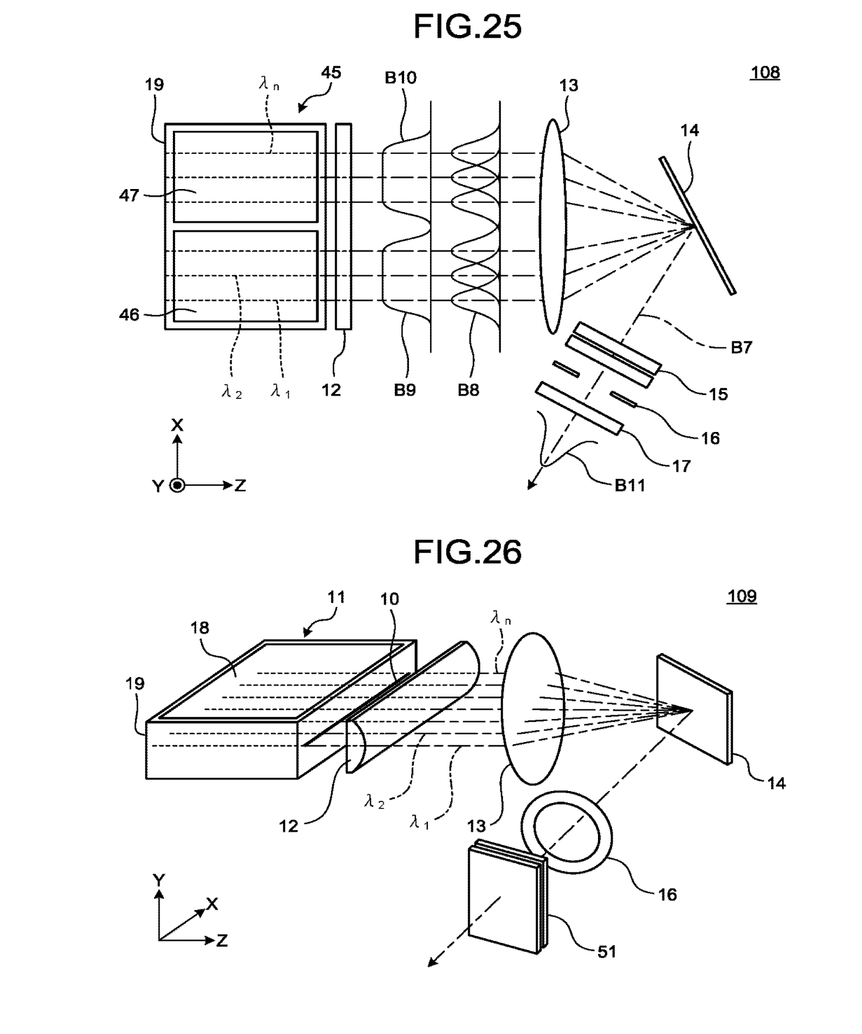

Next, an eighth embodiment is described. FIG. 25 is a top view illustrating the configuration of a semiconductor laser device 108 according to the eighth embodiment. In the semiconductor laser device 108 according to the eighth embodiment, the configuration of the semiconductor laser bar 11 is different from that in the semiconductor laser device 101 according to the first embodiment. In the following descriptions, constituent elements identical to those of the semiconductor laser device 101 according to the first embodiment are denoted by like reference signs and explanations thereof will be omitted.

The semiconductor laser device 108 includes a semiconductor laser bar 45 that includes a plurality of light-emitting regions and that outputs a plurality of beams with different wavelengths from each of the light-emitting regions.

For example, the semiconductor laser bar 45 is constituted by two electrodes 46 and 47 and is divided into two light-emitting regions.

The wavelength-dispersive optical element 14 diffracts condensed beams at a diffraction angle corresponding to their respective wavelengths and superimposes the condensed beams on a single optical axis B7. The beams superimposed on the single optical axis B7 enter the optical filter 15. The optical filter 15 allows only the beams with a plurality of predetermined wavelengths to pass therethrough. The beams having passed through the optical filter 15 are incident on the partially reflecting mirror 17 via the aperture 16.

Because the beams that are incident on the semiconductor laser bar 45 are the beams with the wavelengths that have passed through the optical filter 15, the beams are incident at the determined positions of the semiconductor laser bar 45 that are substantially equally spaced apart. A Gaussian profile B8 is formed as a beam profile as illustrated in FIG. 25 by mode selection determined by the size of the opening of the aperture 16. When beams enter the semiconductor laser bar 45, the beams have two beam profiles B9 and B10, each of which has a generally uniform distribution as illustrated in FIG. 25.

A plurality of beams output from the semiconductor laser bar 45 reciprocate a plurality of times through a resonator constituted between the partially reflecting mirror 17 and the totally reflecting mirror 19. Thereafter, the beams are output from the partially reflecting mirror 17 as a Gaussian profile beam B11.

Therefore, in the semiconductor laser device 108 according to the eighth embodiment, even when the light-emitting region in the semiconductor laser bar 45 is divided into a plurality of regions, beams with a plurality of wavelengths still enter the light-emitting regions of the semiconductor laser bar 45. Accordingly, the semiconductor laser device 108 can obtain the beam profiles B9 and B10 with a substantially uniform distribution in the respective light-emitting regions.

Consequently, the semiconductor laser device 108 can perform laser oscillation in a single mode in the slow-axis direction, improve the quality of a plurality of beams with different wavelengths output from a continuous light-emitting region, and also improve the efficiency, similarly to the semiconductor laser device 101 according to the first embodiment. The light-emitting region is divided into two by dividing the electrode into two. However, it is also possible that the light-emitting region is divided into two by dividing the active layer into two.

### Ninth Embodiment

Next, a ninth embodiment is described. FIG. 26 is a perspective view illustrating the configuration of a semiconductor laser device 109 according to the ninth embodiment. The semiconductor laser device 109 according to the ninth embodiment is different from the semiconductor laser device 101 according to the first embodiment in that the partially reflecting mirror 17 is not included, and instead, an optical filter 51 is located at the position of the partially reflecting mirror 17. In the following descriptions, constituent elements identical to those of the semiconductor laser device 101 according to the first embodiment are denoted by like reference signs and explanations thereof will be omitted.

The semiconductor laser device 109 includes the aperture 16 located on an optical path of a plurality of beams diffracted and superimposed on an identical axis by the wavelength-dispersive optical element 14, and the optical filter 51 located at the subsequent stage of the aperture 16 and on the optical path of the beams superimposed on the identical axis. The wavelength of beams reflected by the optical filter 51 differs periodically.

The totally reflecting mirror 19 is formed on the back side of the semiconductor laser bar 11 to reflect a plurality of beams with different wavelengths that have been reflected by the optical filter 51 and have then returned to the semiconductor laser bar 11.

The wavelengths of a plurality of beams with different wavelengths reflected by the totally reflecting mirror 19 and output from the semiconductor laser bar 11 are respectively identical to the wavelengths of the beams reflected by the optical filter 51.

The optical filter 51 is an etalon. The semiconductor laser device 109 uses the etalon for normal incident.

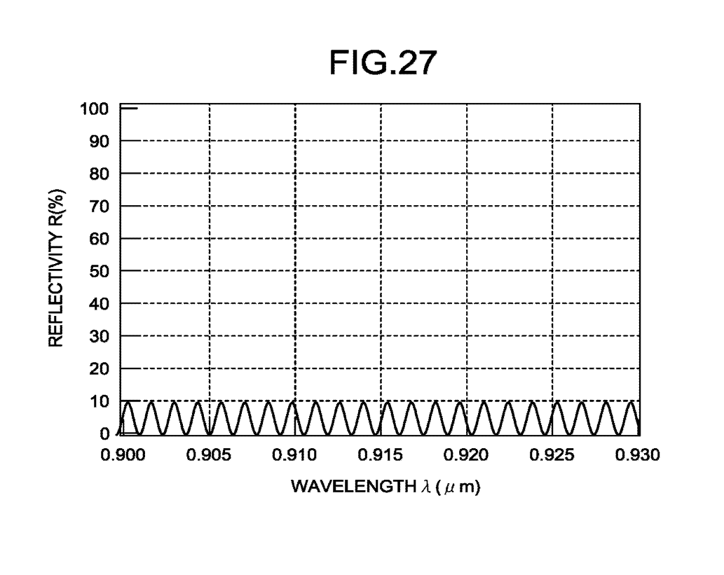

FIG. 27 is a diagram illustrating the reflectivity of an etalon illustrated in FIG. 26. The reflectivity changes periodically relative to the wavelength. The etalon has high reflectivity of 10% at some wavelengths while having low reflectivity of 0%, i.e., having light transmittance of 100% at some wavelengths.

The semiconductor laser device 109 uses an etalon instead of a partially reflecting mirror, and thus only the beams with a plurality of wavelengths at which the reflectivity is high return to the semiconductor laser bar 11 and the semiconductor laser device 109 can perform laser oscillation at the wavelengths of the beams that have returned to the semiconductor laser bar 11.

Consequently, the semiconductor laser device 109 can perform laser oscillation in a single mode in the slow-axis direction, improve the quality of a plurality of beams with different wavelengths output from a continuous light-emitting region, and also improve the efficiency, similarly to the semiconductor laser device 101 according to the first embodiment.

### Tenth Embodiment

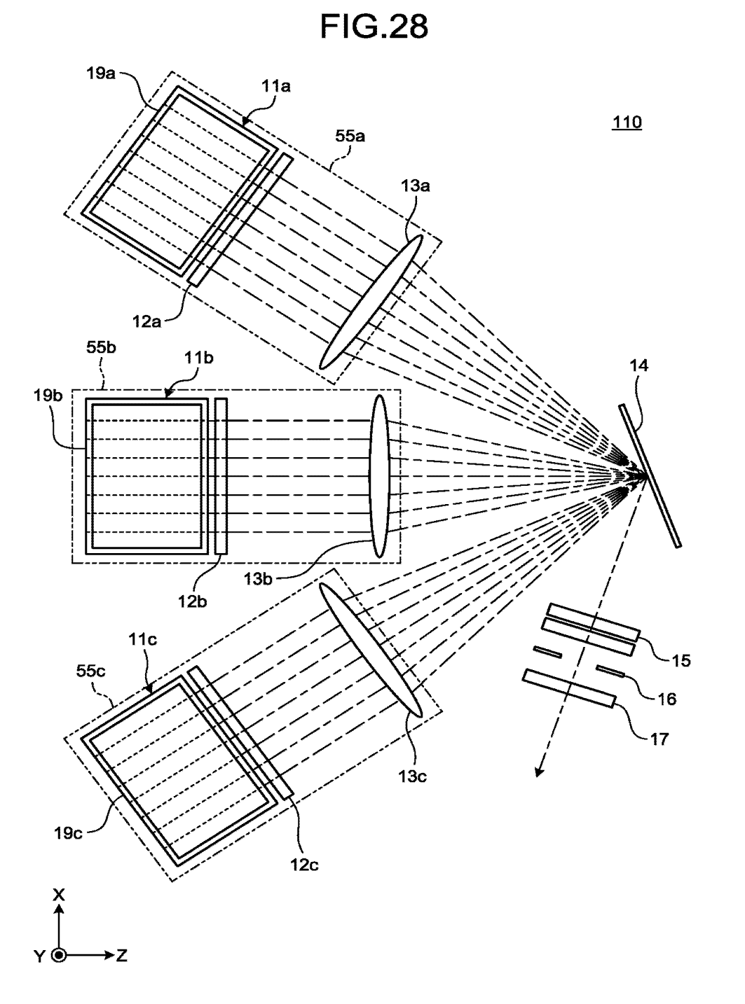

Next, a tenth embodiment is described. FIG. 28 is a top view illustrating the configuration of a semiconductor laser device 110 according to the tenth embodiment. The semiconductor laser device 110 according to the tenth embodiment is different from the semiconductor laser device 101 according to the first embodiment in that the semiconductor laser device 110 includes a plurality of laser condensing groups, each of which is constituted by a semiconductor laser bar and a light-condensing optical system. In the following descriptions, constituent elements identical to those of the semiconductor laser device 101 according to the first embodiment are denoted by like reference signs and explanations thereof will be omitted.

The semiconductor laser device 110 includes a laser condensing group 55a that is constituted by a semiconductor laser bar 11a, a beam divergence-angle correction optical system 12a, and a light-condensing optical system 13a; a laser condensing group 55b that is constituted by a semiconductor laser bar 11b, a beam divergence-angle correction optical system 12b, and a light-condensing optical system 13b; and a laser condensing group 55c that is constituted by a semiconductor laser bar 11c, a beam divergence-angle correction optical system 12c, and a light-condensing optical system 13c.

A plurality of the laser condensing groups 55a, 55b, and 55c are located so as to condense beams at an identical location on the surface of the wavelength-dispersive optical element 14.

A totally reflecting mirror 19a is formed on the surface of the semiconductor laser bar 11a facing the light-emitting surface. A totally reflecting mirror 19b is formed on the surface of the semiconductor laser bar 11b facing the light-emitting surface. A totally reflecting mirror 19c is formed on the surface of the semiconductor laser bar 11c facing the light-emitting surface.

The semiconductor laser device 110 is configured to use the laser condensing groups 55a, 55b, and 55c to condense beams on the wavelength-dispersive optical element 14 and to superimpose the beams with different wavelengths on one another.

The semiconductor laser device 110 can superimpose a larger number of beams with different wavelengths on one another, and therefore can achieve higher output while maintaining high quality of the beams. In the tenth embodiment, the semiconductor laser device 110 is constituted by three laser condensing groups as an example. However, it is also possible that the semiconductor laser device 110 is constituted by two laser condensing groups or four or more laser condensing groups.

### Eleventh Embodiment

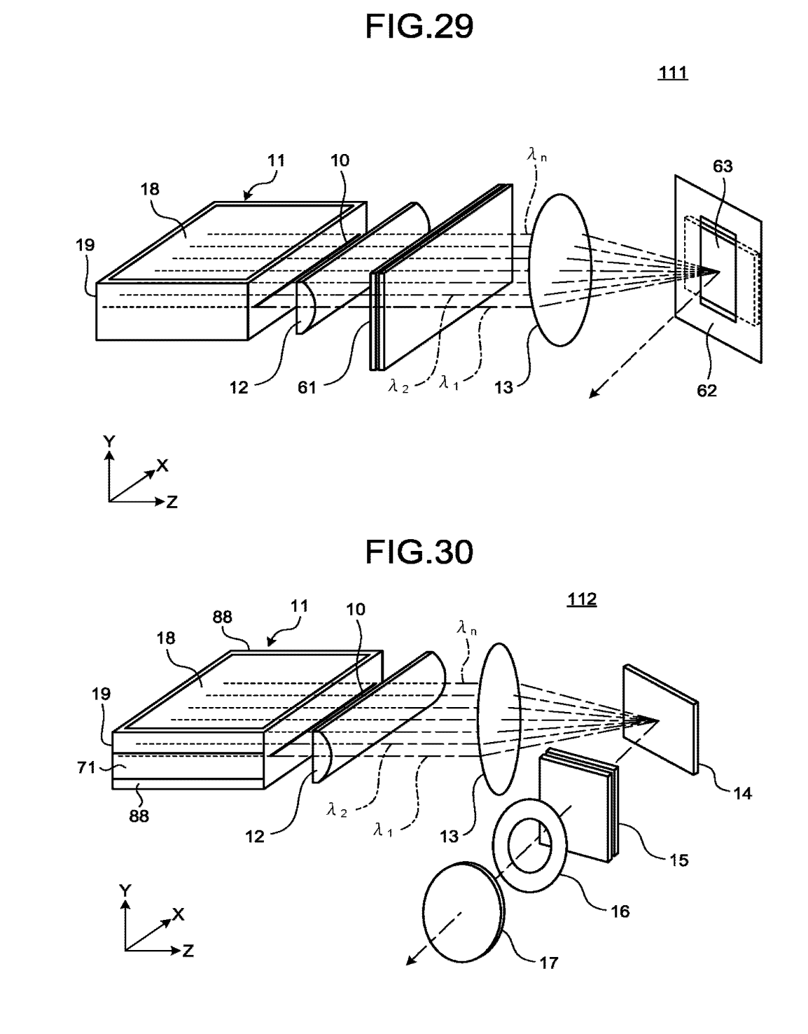

Next, an eleventh embodiment is described. FIG. 29 is a perspective view illustrating the configuration of a semiconductor laser device 111 according to the eleventh embodiment. In the semiconductor laser device 111 according to the eleventh embodiment, the configuration subsequent to the beam divergence-angle correction optical system 12 is different from that in the semiconductor laser device 101 according to the first embodiment. In the following descriptions, constituent elements identical to those of the semiconductor laser device 101 according to the first embodiment are denoted by like reference signs and explanations thereof will be omitted.

The semiconductor laser device 111 includes an optical filter 61 in which the wavelength of the beams that pass therethrough differs periodically; the light-condensing optical system 13 that condenses a plurality of beams having passed through the optical filter 61; an aperture 62; and a wavelength-dispersive optical element 63 that is located at the subsequent stage of the aperture 62 at a position where a plurality of beams are condensed and that has a wavelength dispersing function.

The wavelength-dispersive optical element 63 reflects some of the incident beams. The totally reflecting mirror 19 is formed on the back side of the semiconductor laser bar 11 to reflect a plurality of beams with different wavelengths that have been reflected by the wavelength-dispersive optical element 63 and then have returned to the semiconductor laser bar 11.

The wavelengths of a plurality of beams with different wavelengths reflected by the totally reflecting mirror 19 and output from the semiconductor laser bar 11 are respectively identical to the wavelengths of the beams that pass through the optical filter 61.

Similarly to the optical filter 15 of the semiconductor laser device 101 according to the first embodiment, the optical filter 61 has a periodic transmittance distribution relative to the light wavelength, and is configured to have high transmittance for light with a plurality of beam wavelengths (λ1, λ2, . . . , λn).

The wavelength-dispersive optical element 63 may be configured such that zero-order reflective light returns to the same axis as the incident-light axis. For example, the reflectivity of the wavelength-dispersive optical element 63 may be set to 5% to 20% which is the same as the reflectivity of the partially reflecting mirror 17 in the semiconductor laser device 101 according to the first embodiment. With this configuration, the diffraction efficiency of the wavelength-dispersive optical element 63 is 80% to 95%.

Zero-order reflective light reflected by the wavelength-dispersive optical element 63 reciprocates between the wavelength-dispersive optical element 63 and the totally reflecting mirror 19 formed on the back side of the semiconductor laser bar 11, and laser oscillation is thereby performed. That is, in the semiconductor laser device 111 according to the eleventh embodiment, the wavelength-dispersive optical element 63 serves as an output coupler, and light diffracted by the wavelength-dispersive optical element 63 is an output of the output coupler. A beam mode is selected in accordance with the aperture 62 located immediately before the wavelength-dispersive optical element 63.

Therefore, the semiconductor laser device 111 can exclude a partially reflecting mirror from its constituent elements, and accordingly the entire device can be downsized.

### Twelfth Embodiment

Next, a twelfth embodiment is described. FIG. 30 is a perspective view illustrating the configuration of a semiconductor laser device 112 according to the twelfth embodiment. This configuration is identical to the configuration described in the first embodiment except for an anti-reflection (AR) coating 71. The AR coating 71 is applied to the total internal reflection surface of the semiconductor laser bar 11, on which the totally reflecting mirror 19 is formed, and is also applied to side surfaces 88 of the semiconductor laser bar 11, which are perpendicular to the surface on which the electrode 18 is formed.

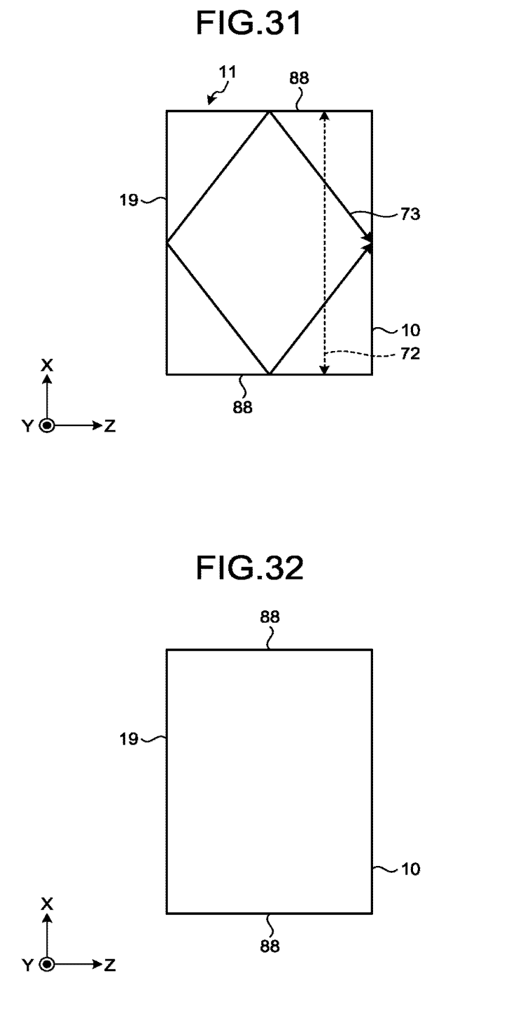

Next, effects of the AR coating 71 are described. FIG. 31 is a top view illustrating a propagation path of unnecessary light within the semiconductor laser bar 11 according to each of the first to eleventh embodiments. FIG. 31 illustrates an exemplary case with the semiconductor laser bar 11 of the semiconductor laser device 101 according to the first embodiment. A dotted double-headed arrow 72 in FIG. 31 illustrates light propagating in the semiconductor laser bar 11.

That is, in the first embodiment, there may be a possibility that light propagates in the lateral direction of the semiconductor laser bar 11 and is then reflected from the side surface 88 of the semiconductor laser bar 11 so as to reciprocate between the side surfaces 88 of the semiconductor laser bar 11 as illustrated by the dotted double-headed arrow 72, thereby causing parasitic oscillation. A solid arrow 73 indicates light that is reflected from the side surfaces 88, the total internal reflection surface, and the light-emitting surface of the semiconductor laser bar 11 and that bounces around in the semiconductor laser bar 11. When there is the light as described above, the light having a large inclination angle is output from the light-emitting surface. Thus, unnecessary light is mixed with laser light oscillating in a direction perpendicular to the total internal reflection surface, which causes degradation of the beam quality of laser light.

In contrast, in the twelfth embodiment, the AR coating 71 is applied to the side surfaces 88 of the semiconductor laser bar 11 as illustrated in FIG. 32. Thus, light as indicated by the above dotted double-headed arrow 72 and the above solid arrow 73 is output without being reflected from the side surfaces 88 of the semiconductor laser bar 11. Accordingly, such light is not substantially present within the semiconductor laser bar 11. This can prevent occurrence of parasitic oscillation and prevent unnecessary light from being mixed with laser light. At this time, it is desirable that the AR coating 71 has reflectivity of 1% or lower.

In the above descriptions, a case where application of the AR coating 71 to the side surfaces 88 of the semiconductor laser bar 11 is applied to the configuration in the first embodiment has been exemplified. However, this case is also applicable to any of the configurations in the first to eleventh embodiments.

### Thirteenth Embodiment

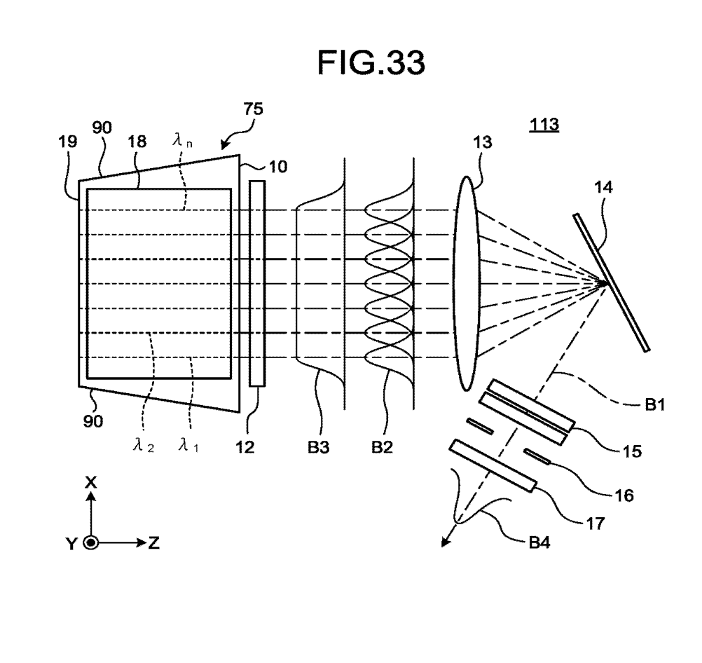

Next, a thirteenth embodiment is described. FIG. 33 is a top view illustrating the configuration of a semiconductor laser device 113 according to the thirteenth embodiment. This configuration is identical to the configuration described in the first embodiment except that a semiconductor laser bar 75 has inclined side surfaces 90. In the thirteenth embodiment, each of the side surfaces 90 of the semiconductor laser bar 75 is not perpendicular but is inclined to the surface on which the totally reflecting film 19 is formed or the surface formed with the light-emitting region 10, as illustrated in FIG. 33.

Due to the above configuration, even when there is light propagating in the lateral direction of the semiconductor laser bar 11 as described in the twelfth embodiment, the light does not reciprocate between the side surfaces of the semiconductor laser bar 75. This can prevent parasitic oscillation. It is sufficient if the side surfaces 90 are slightly inclined, for example, by 10 from the direction perpendicular to the surface on which the totally reflecting mirror 19 is formed or the surface formed with the light-emitting region 10.

In the above descriptions, a case where the inclined side surfaces 90 of the semiconductor laser bar 75 are applied to the configuration in the first embodiment has been exemplified. However, this is also applicable to any of the configurations in the first to twelfth embodiments.

### Fourteenth Embodiment

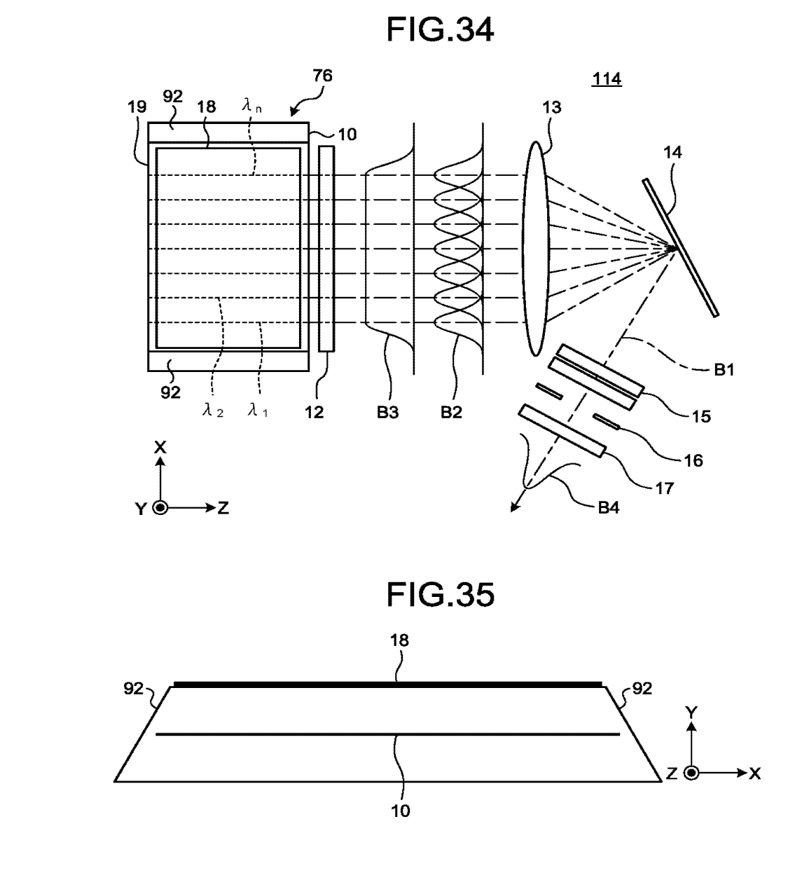

Next, a fourteenth embodiment is described. FIG. 34 is a top view illustrating the configuration of a semiconductor laser device 114 according to the fourteenth embodiment. FIG. 35 is a front view of a semiconductor laser bar 76 according to the fourteenth embodiment as viewed from the surface formed with the light-emitting region 10. This configuration is identical to the configuration described in the first embodiment except that side surfaces 92 of the semiconductor laser bar 76 are inclined. As illustrated in FIG. 35, each of the side surfaces 92 is not perpendicular but is inclined to the surface on which the electrode 18 is formed.

Due to the above configuration, even when there is light propagating in the lateral direction of the semiconductor laser bar 11 as described in the twelfth embodiment, light reflected from the side surfaces 92 of the semiconductor laser bar 76 does not return to the light-emitting region formed of an active layer in the semiconductor laser bar 76. Therefore, the light does not reciprocate between the side surfaces 92 of the semiconductor laser bar 76. This can prevent parasitic oscillation. It is sufficient if the side surfaces 92 are slightly inclined, for example, by 0.1° from the direction perpendicular to the surface of the electrode 18.

In the above descriptions, a case where the inclined side surfaces of the semiconductor laser bar are applied to the configuration in the first embodiment has been exemplified. However, this case is also applicable to any of the configurations in the first to twelfth embodiments.

### Fifteenth Embodiment

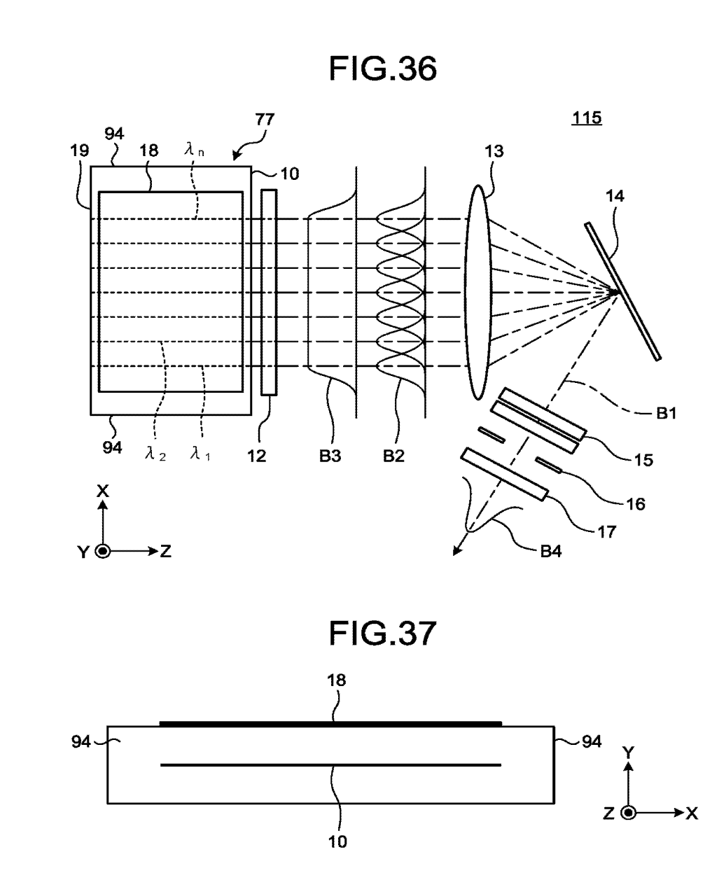

Next, a fifteenth embodiment is described. FIG. 36 is a top view illustrating the configuration of a semiconductor laser device 115 according to the fifteenth embodiment. This configuration is identical to the configuration described in the first embodiment except that the electrode 18 of a semiconductor laser bar 77 is not formed over the entire surface of the semiconductor laser bar 77, and current does not flow in a region near side surfaces 94 of the semiconductor laser bar 77 in a direction perpendicular to the optical axis of laser light. FIG. 37 is a front view of the semiconductor laser bar 77 according to the fifteenth embodiment as viewed from the surface formed with the light-emitting region 10. As illustrated in FIG. 37, the electrode 18 and the light-emitting region 10 are not present near the ends of the semiconductor laser bar 77, i.e., near the side surfaces 94.

Due to the above configuration, even when there is light propagating in the lateral direction of the semiconductor laser bar 11 as described in the twelfth embodiment, the light is absorbed in the semiconductor laser bar 77 before reaching the side surfaces 94 of the semiconductor laser bar 77. Therefore, the light does not return to the light-emitting region formed of an active layer in the semiconductor laser bar 77. Accordingly, light does not reciprocate between the side surfaces 94 of the semiconductor laser bar 77. This can prevent parasitic oscillation. It is sufficient if the length of a region through which current does not pass is 100 μm in the lateral direction. In a general type of stripe-electrode LD bar, the distance between adjacent electrodes is approximately 100 μm and laser light is sufficiently separated from each other between the adjacent active regions. That is, when the electrode 18 is distant from the side surface 94 by 100 μm, it is possible to prevent light from propagating and to sufficiently absorb light.

In the above descriptions, the light-emitting region is limited by the electrode 18. However, it is also possible that the light-emitting region is limited by an active layer. That is, the light-emitting region can be limited by not forming an active layer in an area within approximately 100 μm from the side surfaces 94.

In the above descriptions, a case where the inclined side surfaces 94 of the semiconductor laser bar 77 are applied to the configuration in the first embodiment has been exemplified. However, this is also applicable to any of the configurations in the first to fourteenth embodiments.

The configurations described in the embodiments are only examples of the content of the present invention and may be combined with other well-known techniques or may be partially modified or omitted without departing from the scope of the present invention. For example, lenses or the like (not illustrated) may be provided in an optical path so as to adjust the beam radius.

### REFERENCE SIGNS LIST

101, 102, 103, 104, 105, 106, 107, 108, 109, 110, 111, 112, 113, 114, 115 semiconductor laser device, 10 light-emitting region, 11, 11a, 11b, 11c, 45 semiconductor laser bar, 12, 12a, 12b, 12c beam divergence-angle correction optical system, 13, 13a, 13b, 13c light-condensing optical system, 14, 63 wavelength-dispersive optical element, 15, 51, 61 optical filter, 16, 21, 25, 62 aperture, 17, 26, 36 partially reflecting mirror, 18, 46, 47 electrode, 19, 19a, 19b, 19c totally reflecting mirror, 22, 23 cylindrical lens, 31 light-condensing optical system, 32, 35 fiber Bragg grating, 41 prism, 55a, 55b, 55c laser condensing group, 71 AR (Anti Reflection) coating, 72 light reciprocating in lateral direction of semiconductor laser bar, 73 light circulating inside semiconductor laser bar, 75 semiconductor laser bar with inclined side surfaces, 76 semiconductor laser bar with inclined side surfaces, 77 semiconductor laser bar without electrode and light-emitting region near side surfaces, 88, 90, 92, 94 side surface.

1-13. (canceled)

14: A semiconductor laser device comprising:
a semiconductor laser bar to output a plurality of beams with different wavelengths from a single light-emitting region;
a light-condensing lens to condense the beams;
a wavelength-dispersive optical element located at a position where the beams are condensed, having a wavelength dispersing function, and superimposing the beams on an identical axis;
an optical filter through which only beams with a plurality of predetermined wavelengths pass, the beams superimposed by the wavelength-dispersive optical element entering the optical filter;
an aperture located on an optical path of the superimposed beams; and
a partially reflecting mirror on which the beams that pass through the aperture are incident and that allows some of the beams to enter the semiconductor laser bar.

15: The semiconductor laser device according to claim 14, wherein the light-emitting region is formed by forming an electrode on the semiconductor laser bar.

16: The semiconductor laser device according to claim 14, wherein the beams are superimposed on each other at an output position of the semiconductor laser bar.

17: The semiconductor laser device according to claim 16, wherein
a relation between “w” that is a beam radius of each of the beams and Pitch that is an interval between optical-axis positions of two adjacent beams of the beams at the output position of the semiconductor laser bar satisfies w/Pitch >=0.8.

18: The semiconductor laser device according to claim 14, wherein the optical filter is an etalon.

19: The semiconductor laser device according to claim 14, wherein the semiconductor laser bar includes a plurality of light-emitting regions and outputs a plurality of beams with different wavelengths from each of the light-emitting regions.

20: The semiconductor laser device according to claim 14, comprising a plurality of laser condensing groups, each of which includes the semiconductor laser bar, a beam divergence-angle correction optical system, and the light-condensing lens, wherein
the laser condensing groups are located in such a position that beams are condensed at an identical location on a surface of the wavelength-dispersive optical element.

21: The semiconductor laser device according to claim 14, wherein a beam output from the semiconductor laser bar has a Gaussian profile.

22: A semiconductor laser device comprising:
a semiconductor laser bar to output a plurality of beams with different wavelengths from a single light-emitting region;
a light-condensing lens to condense the beams;
a wavelength-dispersive optical element located at a position where the beams are condensed and having a wavelength dispersing function;
an aperture located on an optical path of the beams diffracted and superimposed on an identical axis by the wavelength-dispersive optical element; and
a partially reflecting mirror that is located on an optical path of the beams superimposed on the identical axis, on which the beams that pass through the aperture are incident, and a reflectivity of which changes periodically in a wavelength area.

23: The semiconductor laser device according to claim 22, wherein the semiconductor laser bar includes a plurality of light-emitting regions and outputs a plurality of beams with different wavelengths from each of the light-emitting regions.

24: The semiconductor laser device according to claim 22, comprising a plurality of laser condensing groups, each of which includes the semiconductor laser bar, a beam divergence-angle correction optical system, and the light-condensing lens, wherein
the laser condensing groups are located in such a position that beams are condensed at an identical location on a surface of the wavelength-dispersive optical element.

25: The semiconductor laser device according to claim 22, wherein a beam output from the semiconductor laser bar has a Gaussian profile.

26: A semiconductor laser device comprising:
a semiconductor laser bar to output a plurality of beams with different wavelengths from a single light-emitting region;
a first light-condensing lens to condense the beams;
a wavelength-dispersive optical element located at a position where the beams are condensed and having a wavelength dispersing function;
a second light-condensing lens to condense the superimposed beams, the second light-condensing lens being located on an optical path of beams diffracted and superimposed on an identical axis by the wavelength-dispersive optical element; and
a fiber Bragg grating on which beams condensed by the second light-condensing lens are incident, wherein
the fiber Bragg grating selectively reflects only wavelengths of the beams so as to be returned to the semiconductor laser bar.

27: The semiconductor laser device according to claim 26, wherein the semiconductor laser bar includes a plurality of light-emitting regions and outputs a plurality of beams with different wavelengths from each of the light-emitting regions.

28: The semiconductor laser device according to claim 26, comprising a plurality of laser condensing groups, each of which includes the semiconductor laser bar, a beam divergence-angle correction optical system, and the light-condensing lens, wherein
the laser condensing groups are located in such a position that beams are condensed at an identical location on a surface of the wavelength-dispersive optical element.

29: The semiconductor laser device according to claim 26, wherein a beam output from the semiconductor laser bar has a Gaussian profile.
